(19) United States
(12) Patent Application Publication
(10) Pub. No.: US 2015/0016070 A1
(43) Pub. Date: Jan. 15, 2015

(54) CONDUCTIVE STRUCTURE AND DEVICE WITH THE CONDUCTIVE STRUCTURE AS ELECTRODE

(71) Applicant: Industrial Technology Research Institute, Hsinchu (TW)

(72) Inventor: Yi-Ming Chang, Hsinchu City (TW)

(73) Assignee: Industrial Technology Research Institute, Hsinchu (TW)

(21) Appl. No.: 14/135,590

(22) Filed: Dec. 20, 2013

Related U.S. Application Data
(60) Provisional application No. 61/844,435, filed on Jul. 10, 2013.

(51) Int. Cl. H01B 5/00; H05K 1/02

(52) U.S. Cl. CPC H01B 5/002; H05K 1/0296
USPC 361/748; 174/126.1

(57) ABSTRACT

Provided is a conductive structure and a device with the conductive structure as an electrode. The conductive structure includes a reduced metal layer and an overlapping structure formed by nano metal wires. The overlapping structure has at least one connecting portion, and the reduced metal layer covers the nano metal wires at the connecting portions.

### CROSS REFERENCE TO RELATED APPLICATION

This application claims the priority benefit of U.S. provisional application Ser. No.. 61/844,435, filed on Jul. 10, 2013. The entirety of the above-mentioned patent application is hereby incorporated by reference herein and made a part of specification.

### TECHNICAL FIELD

The disclosure is related to a conductive structure and a device with the conductive structure as an electrode.

### BACKGROUND

When nano metal wires are stacked into a conductive network structure, the wires are connected to one another via physical contact. The physical contact readily generates a greater resistance between the wires. Moreover, due to the absence of a structure for fixing the nano metal wires, reliability is readily decreased (may cause wire dislocation) during mechanical contact or when the substrate is bent.

### SUMMARY

A conductive structure of an embodiment of the disclosure includes an overlapping structure formed by nano metal wires and a reduced metal layer. The overlapping structure has at least one connecting portion, and the reduced metal layer covers the nano metal wires at the connecting portions.

A device of another embodiment of the disclosure includes a plurality of electrode structures, wherein at least one of the electrode structures is the conductive structure above.

In order to the make aforementioned and other features and advantages of the disclosure comprehensible, embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a conductive structure according to the first embodiment of the disclosure.

FIG. 2A is an enlarged schematic diagram of a connecting portion of FIG. 1.

FIG. 2B is a schematic cross-sectional diagram of the nano metal wires of FIG. 1 covered by a reduced metal layer.

FIG. 3A-FIG. 3C are respectively schematic cross-sectional diagrams of a variety of organic light-emitting diodes (OLED)/organic solar cells (OPV) according to the second embodiment of the disclosure.

FIG. 4A-FIG. 4C are respectively schematic cross-sectional diagrams of a variety of touch panels (TP) according to the third embodiment of the disclosure.

FIG. 5 is a diagram of the fabrication process of a conductive structure according to the fourth embodiment of the disclosure.

FIG. 6 is an SEM micrograph of an overlapping structure of experimental embodiment 1.

FIG. 7 is an SEM micrograph of a conductive film of experimental embodiment 1.

FIG. 8 is a curve diagram between sheet resistance and concave bending cycle of test 1.

FIG. 9 is a curve diagram between sheet resistance and convex bending cycle of test 1.

FIG. 10 is a curve diagram between sheet resistance and concave bending cycle of test 2.

FIG. 11 is a curve diagram between sheet resistance and convex bending cycle of test 2.

FIG. 12A is an SEM micrograph of a nano metal wire conductive film of test 3.

FIG. 12B is an SEM micrograph of a conductive film of experimental embodiment 3 of test 3.

FIG. 13 is a TEM micrograph of an overlapping structure of experimental embodiment 4.

FIG. 14 is a TEM micrograph of a conductive film of experimental embodiment 4.

FIG. 15 is a curve diagram of the relationship between reaction time and sheet resistance of a conductive film of each of experimental embodiment 4 and experimental embodiment 5.

### DETAILED DESCRIPTION OF DISCLOSED EMBODIMENTS

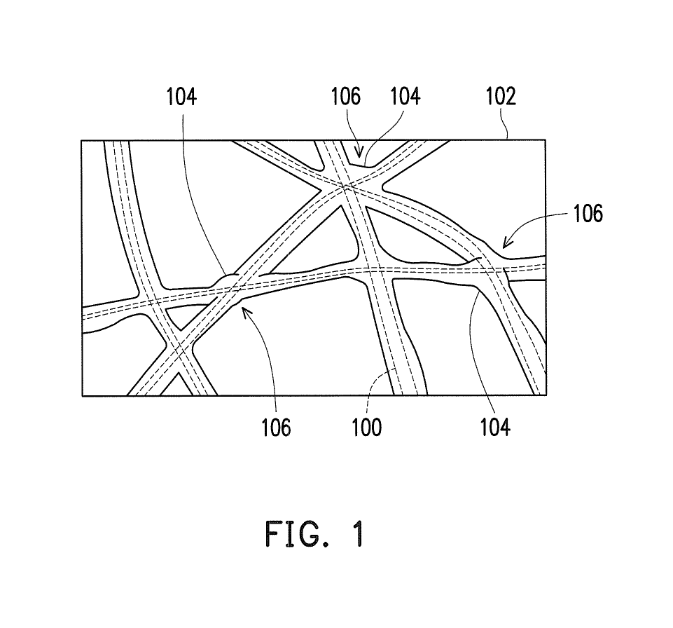

FIG. 1 is a schematic diagram of a conductive structure according to the first embodiment of the disclosure.

Referring to FIG. 1, a conductive structure of the present embodiment includes an overlapping structure 102 formed by nano metal wires 100 and a reduced metal layer 104. The overlapping structure 102 has at least one connecting portion 106 and the reduced metal layer 104 covers the nano metal wires 100 of the connecting portions 106. Since the reduced metal layer 104 is a metal formed by a reduction reaction, the nano metal wires 100 originally having only physical contact at the connecting portions 106 are covered by the reduced metal layer 104, thereby forming a junction. The resistance of the conductive structure is decreased. Therefore, the conductive structure of the present embodiment not only can decrease the sheet resistance thereof due to the improvement of contact resistance, but can also achieve a continuous phase overlapping structure 102 due to the tight connections in the nano metal wires 100. The conductive structure of the present embodiment has better mechanical properties during bending and does not readily generate wire displacement or rupture. The material of each of the reduced metal layer 104 and the nano metal wires 100 may be the same or different. The material of the nano material wires 100 includes, for instance, silver, copper, nickel, or an alloy thereof; and the material of the reduced metal layer 104 includes, for instance, silver, copper, nickel, titanium, or an alloy thereof. Moreover, as shown in FIG. 1, the reduced metal layer 104 may cover the nano metal wires 100 not at the connecting portions 106. The nano metal wires 100 may be a covering structure formed by the combination of a plurality of metal layers.

The overlapping structure 102 in FIG. 1 may be a layered or network structure. The denser the nano metal wires 100 contained in the overlapping structure 102, the better the conductivity. Conversely, the sparser the nano metal wires 100 contained in the overlapping structure 102, the better the light transmittance. Therefore, if the light transmittance of the conductive structure of the present embodiment allows, then the conductive structure may be applied to a transparent conductive film. Moreover, due to the tight connections in the nano metal wires 100, the reliability of the transparent conductive film can be increased.

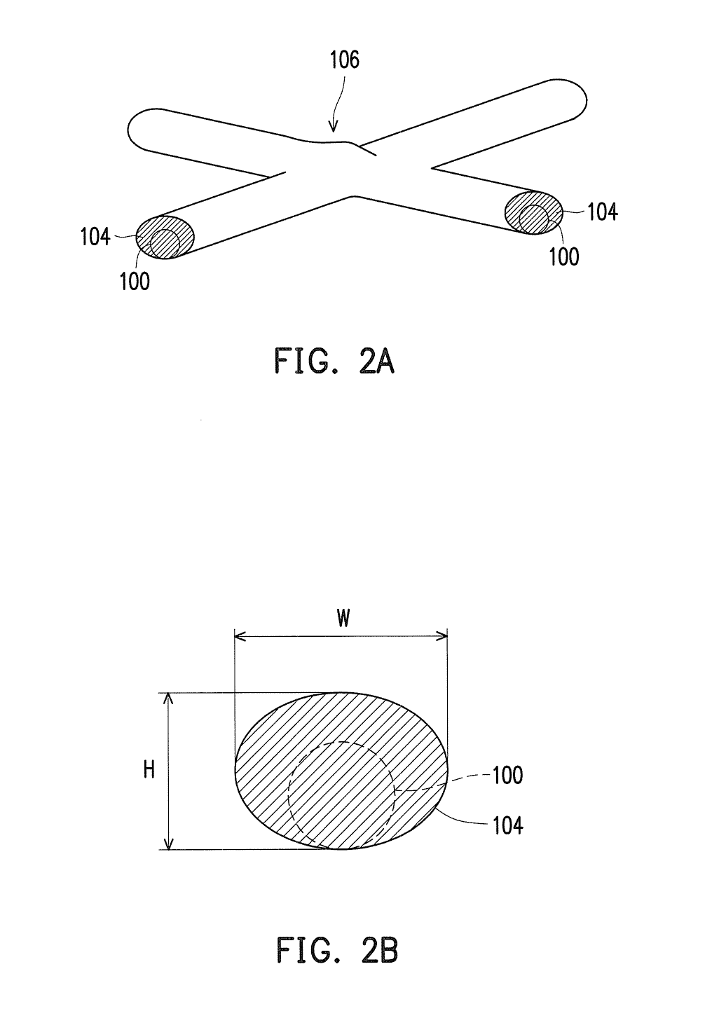

The reduced metal layer 104 may be continuously formed on the exposed surface of the nano metal wires 100. It may be not easy for the reduced metal layer 104 to continuously form at the contact portions of the nano metal wires 100 and the substrate (not shown) thereunder, and the cross-sectional width of the connecting portions 106 is wider, and can be, for instance, at least 1.5 times greater than the cross-sectional height thereof, as shown in FIG. 2A. In terms of only the reduced metal layer 104 and the nano metal wires 100 not at the connecting portions 106, a cross-sectional (refer to FIG. 2B) width W of the nano metal wires 100 covered by the reduced metal layer 104 may be wider, and the cross-sectional width W is, for instance, at least 1.5 times greater than a cross-sectional height H thereof

The conductive structure may be applied in an electrode structure of various devices. For instance, the conductive structure can be applied in a device such as an organic light-emitting diode (OLED), an organic solar cell (OPV), or a touch panel (TP).

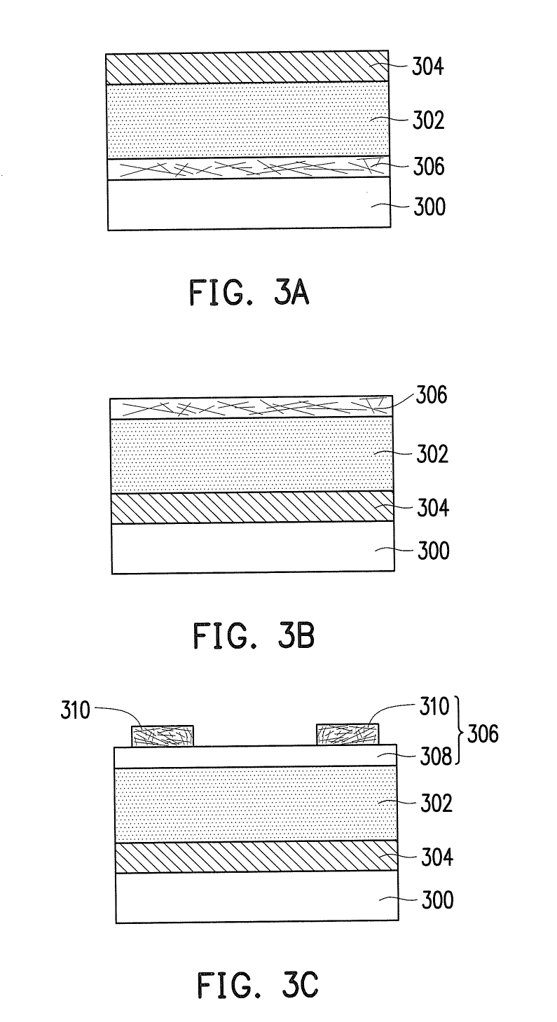

FIG. 3A-FIG. 3C are respectively schematic cross-sectional diagrams of a variety of organic light-emitting diodes (OLED)/organic solar cells (OPV) according to the second embodiment of the disclosure.

Referring to FIG. 3A-FIG. 3C, both the OLED and the OPV at least have a substrate 300, an organic layer 302, an electrode 304, and a transparent conductive layer 306, the two devices are described together in the second embodiment.

In FIG. 3A, the transparent conductive layer 306 can use the conductive structure of the first embodiment as an electrode alone. The wire diameter of the nano metal wires (refer to 100 of FIG. 1) is, for instance, about 10 nm to about 500 nm, and the height of the connecting portions (refer to 106 of FIG. 1) is, for instance, between 20 nm and 2000 nm. The range of sheet resistance of the conductive structure of the first embodiment used as the transparent conductive layer 306 is between about 0.1 Ω/□ and about 500 Ω/□, and the range of light transmittance is about 50% to about 99%.

Moreover, the transparent conductive layer 306 of FIG. 3A may use the conductive structure of the first embodiment as an auxiliary electrode. In other words, in addition to the original common transparent conductive oxide (TCO) or hole injection material, a portion of the conductive structure of the first embodiment may be added to the transparent conductive layer 306 to decrease the sheet resistance of the overall transparent conductive layer 306. In this case, the wire diameter of the nano metal wires is, for instance, 20 nm-500 μm and the height of the connecting portions is, for instance, 40 nm-1000 μm. In addition, in the transparent conductive layer 306 of FIG. 3A, nano metal wires and the conductive structure of the first embodiment may be added in the TCO at the same time to decrease the sheet resistance of the overall transparent conductive layer 306.

In FIG. 3B, the electrode 304 is disposed between the substrate 300 and the organic layer 302, and the transparent conductive layer 306 is on the organic layer 302. The material of the transparent conductive layer 306 is as shown in FIG. 3A, and includes all of the conductive structure of the first embodiment used as an electrode alone, the TCO and the conductive structure (auxiliary electrode) of the first embodiment, the TCO and the conductive structure of the first embodiment with the nano metal wires, the hole injection material and the conductive structure of the first embodiment, and the hole injection material and the conductive structure of the first embodiment with the nano metal wires.

In FIG. 3C, the transparent conductive layer 306 includes a TCO layer 308 and an auxiliary electrode 310. The auxiliary electrode 310 may be arranged on the surface of the TCO layer 308 in a stripe or a comb. If light transmittance is irrelevant, then the conductive structure of the first embodiment used in the auxiliary electrode 310 may be a dense overlapping structure with better conductivity.

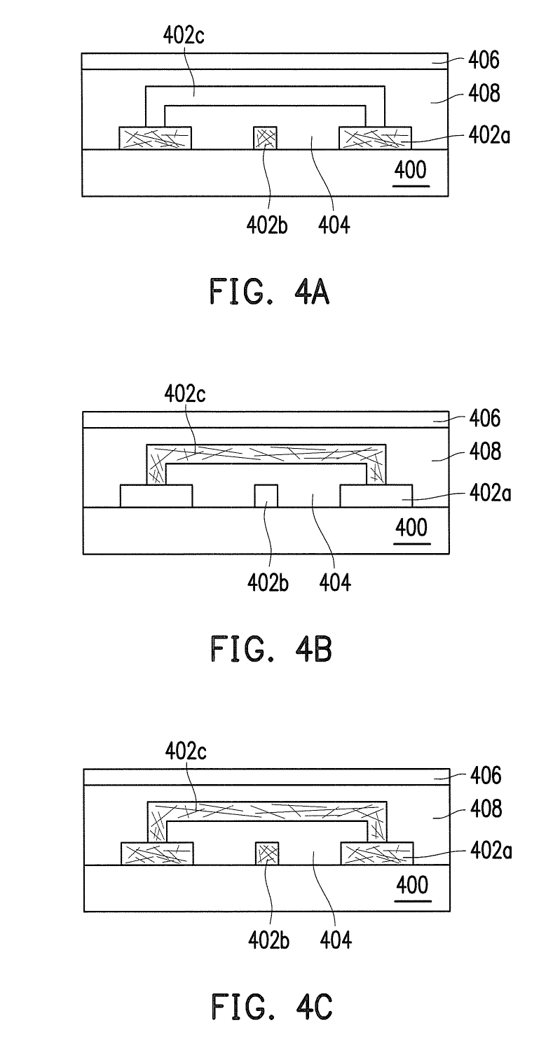

FIG. 4A-FIG. 4C are respectively schematic cross-sectional diagrams of a variety of touch panels (TP) according to the third embodiment of the disclosure.

Referring to FIG. 4A-FIG. 4C, a TP at least has a substrate 400, electrically isolated transparent conductive layers 402a and 402b, a bridge structure 402c, an insulating layer 404, a cover 406, and an optical adhesive layer 408. In FIG. 4A, the transparent conductive layers 402a and 402b fabricated on the same layer can use the conductive structure of the first embodiment. The wire diameter of the nano metal wires (refer to 100 of FIG. 1) is, for instance, about 10 nm to about 500 •m, and the height of the connecting portions (refer to 106 of FIG. 1) is, for instance, between 20 nm and 1000 μm. The range of sheet resistance of the conductive structure of the first embodiment used as the transparent conductive layers 402a and 402b is between about 0.01 Ω/□ and about 500 Ω/□, and the range of light transmittance is about 50% to about 99%. The bridge structure 402c is fabricated after the transparent conductive layers 402a and 402b on the same layer are completed, TCO can be used. Conversely, in FIG. 4B, the transparent conductive layers 402a and 402b fabricated on the same layer are fabricated first and are used as the TCO, and the bridge structure 402c fabricated afterward uses the conductive structure of the first embodiment. In addition, in FIG. 4C, the conductive structure of the first embodiment is used to completely replace all of the transparent conductive layers 402a and 402b and the bridge structure 402c.

The conductive structure of an embodiment of the disclosure does not readily generate wire displacement due to the tight connections in the nano metal wires, when the conductive structure is applied in a TP, an overcoat traditionally needed when nano metal wires are used can be omitted.

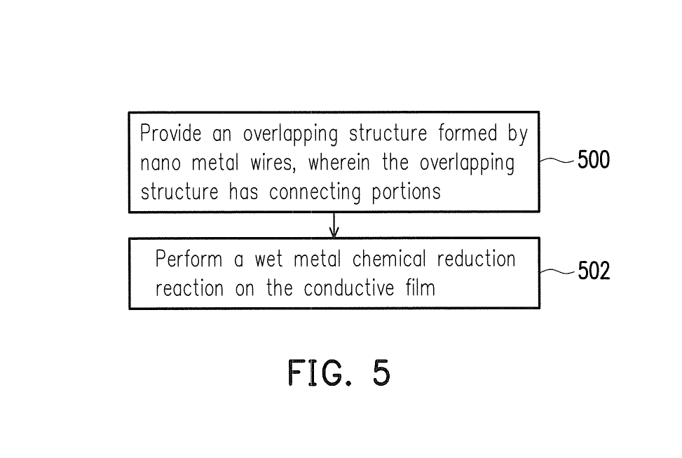

FIG. 5 is a diagram of the fabrication process of a conductive structure according to the fourth embodiment of the disclosure.

Referring to FIG. 5, the method of the fourth embodiment includes step 500, in which an overlapping structure formed by nano metal wires is provided, and the overlapping structure has at least one connecting portion. The material of the nano metal wires 100 is, for instance, silver, copper, nickel, or an alloy thereof, and the nano metal wires 100 may be a covering structure formed by the combination of a plurality of metal layers. Moreover, the overlapping structure may be a layered or network structure, but the disclosure is not limited thereto.

In step 502, a wet metal chemical reduction reaction is performed on a conductive film such that a metal atom formed by the wet metal chemical reduction reaction covers the nano metal wires at the connecting portions. The steps of the wet metal chemical reduction reaction include, for instance: using a reducing agent to reduce a metal ion complex to the metal ion to obtain a metal reducing solution, and then placing the overlapping structure in the metal reducing solution to foil the reduced metal layer covering the nano metal wires. Moreover, the thickness of the reduced metal layer may be controlled by the following parameters: (1) the time of the overlapping structure placed in the metal reducing solution, (2) the temperature when the overlapping structure is placed in the metal reducing solution, or (1) the concentration of the metal reducing solution. However, the disclosure is not limited thereto. When a different type of metal ion is used, the parameters of the wet metal chemical reduction reaction may be affected, thereby affecting the formation of the reduced metal layer.

The effect of an embodiment of the disclosure is described below with experiments.

### Experimental Embodiment 1

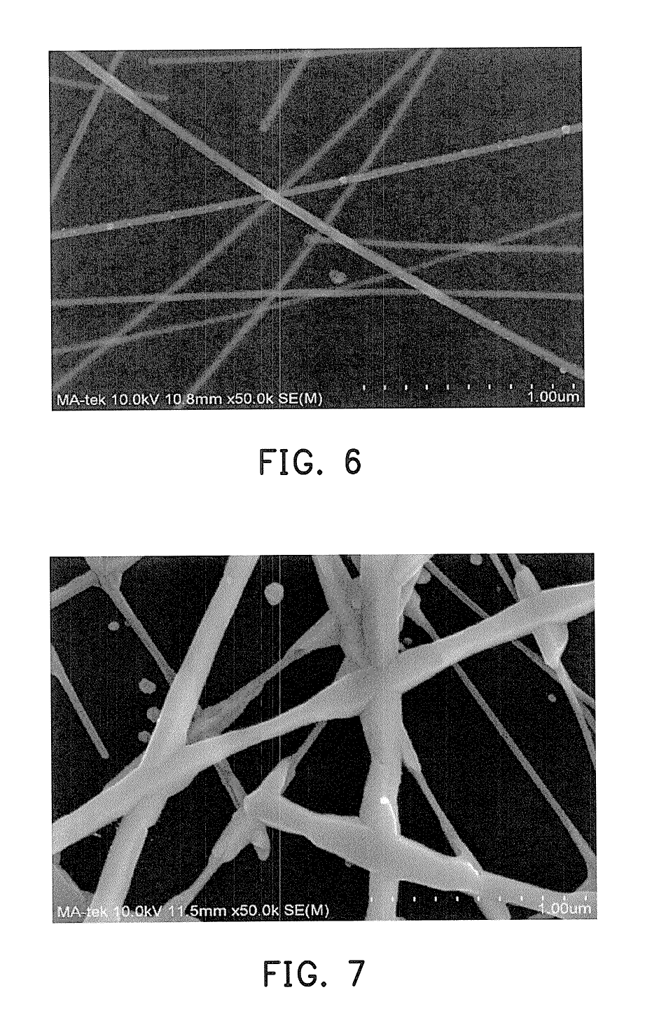

A coating solution of Ag nano wires (NW) is coated on a glass substrate through a slot-die to obtain a transparent conductive film (transparency of about 87% at 550 nm wavelength) with a sheet resistance of 20 Ω/□. The surface morphology thereof is as the overlapping structure shown in the SEM micrograph of FIG. 6. It can be known from FIG. 6 that, the overlapping structure has significant variations in depth of field. In other words, the Ag NWs are only in contact with one another in an overlapping manner before the reaction.

The preparation of the metal reducing solution includes, for instance: adding 3 mL of an aqueous solution of 0.25M NaOH to 5 mL of an aqueous solution of 0.06M AgNO₃ to generate Ag₂O precipitation. The formula of the chemical reaction is as follows.

2AgNO₃(aq)+2NaOH(aq)→Ag₂O(s)+2NaNO₃(aq)+H₂O(l)

After stirring, an aqueous solution of 0.2M NH₃ is added to the Ag₂O mixture via titration until Ag₂O is completely reacted and is no longer visible after stirring. A Ag(NH₃)₂⁺ complex ion compound is thus formed. The formula of the chemical reaction is as follows.

Ag₂O(s)+4NH₃(aq)+H₂O(l)→2[Ag(NH₃)₂]⁺(aq)+2OH⁻(aq)

Next, 0.25 mL of an aqueous solution of glucose with a concentration of 1% is added to the Ag(NH₃)₂⁺solution to initiate the reduction reaction of Ag. Suspended matter then results in the solution, wherein the suspended matter is Ag metal formed by the reduction. The formula of the chemical reaction is as follows.

RCHO(aq)+2[Ag(NH₃)₂]⁺(aq)+3OH⁻(aq)→RCOO⁻(aq)+2Ag(s)+4NH₃(aq)+2H₂O(l)

A substrate provided with an overlapping structure is immersed in the reaction solution for about 240 seconds such that Ag formed by the reduction grows on the Ag NW to form a continuous phase structure. The surface morphology thereof after the reaction is as shown in the SEM micrograph of FIG. 7. After the Ag NW structure is covered by the reduced silver, the contact portions form a continuous phase structure, and the original variations in depth of field are removed. The sheet resistance of the conductive film of the continuous phase structure may be decreased to about 5 Ω/□ due to the connections between the wires.

### Experimental Embodiment 2

A coating solution of Ag NW is coated on a glass substrate through a slot-die to obtain a transparent conductive film (transparency of about 87% at 550 nm wavelength) with a sheet resistance of 20 Ω/□.

The preparation of the metal reducing solution includes, for instance: adding 3 mL of an aqueous solution of 0.25M NaOH to 5 mL of an aqueous solution of 0.06M AgNO₃ to generate Ag₂O precipitation. After stirring, an aqueous solution of 0.1 M NH₃ is added to the Ag₂O mixture via titration until Ag₂O is completely reacted and is no longer visible after stirring. A Ag(NH₃)₂⁺ complex ion compound is thus formed. 0.25 mL of an aqueous solution of glucose with a concentration of 1% is added to the Ag(NH₃)₂⁺ solution to initiate the reduction reaction of Ag. Suspended matter then results in the solution, wherein the suspended matter is Ag metal formed by the reduction.

A substrate coated with the Ag NW is respectively immersed in the reaction solution for, for instance, 30 seconds, 60 seconds, and 120 seconds so as to grow the Ag formed by the reduction on the Ag NW to form a continuous phase structure. The sheet resistances of the conductive film after the reaction can be decreased to 16 Ω/□, 12 Ω/□, and 10 Ω/□.

### Experimental Embodiment 3

A coating solution of Ag NW is coated on a polyethylene terephthalate (PET) substrate to obtain a transparent conductive film with a sheet resistance of 20 Ω/□.

The preparation of the metal reducing solution includes, for instance: adding 3 mL of an aqueous solution of 0.25M NaOH to 5 mL of an aqueous solution of 0.06M AgNO₃ to generate Ag₂O precipitation. After stirring, an aqueous solution of 0.1M NH₃ is added to the Ag₂O mixture via titration until Ag₂O is completely reacted and is no longer visible after stirring. A Ag(NH₃)₂⁺ complex ion compound is thus formed.

0.25 mL of an aqueous solution of glucose with a concentration of 1% is added to the Ag(NH₃)₂⁺ solution to initiate the reduction reaction of Ag. Suspended matter then results in the solution, wherein the suspended matter is Ag metal formed by the reduction.

A substrate coated with the Ag NW is immersed in the reaction solution for about 60 seconds so as to grow the Ag formed by the reduction on the Ag NW to form a continuous phase structure. The sheet resistance of the conductive film can be decreased to 7 Ω/□ due to the connections between the wires.

Test 1

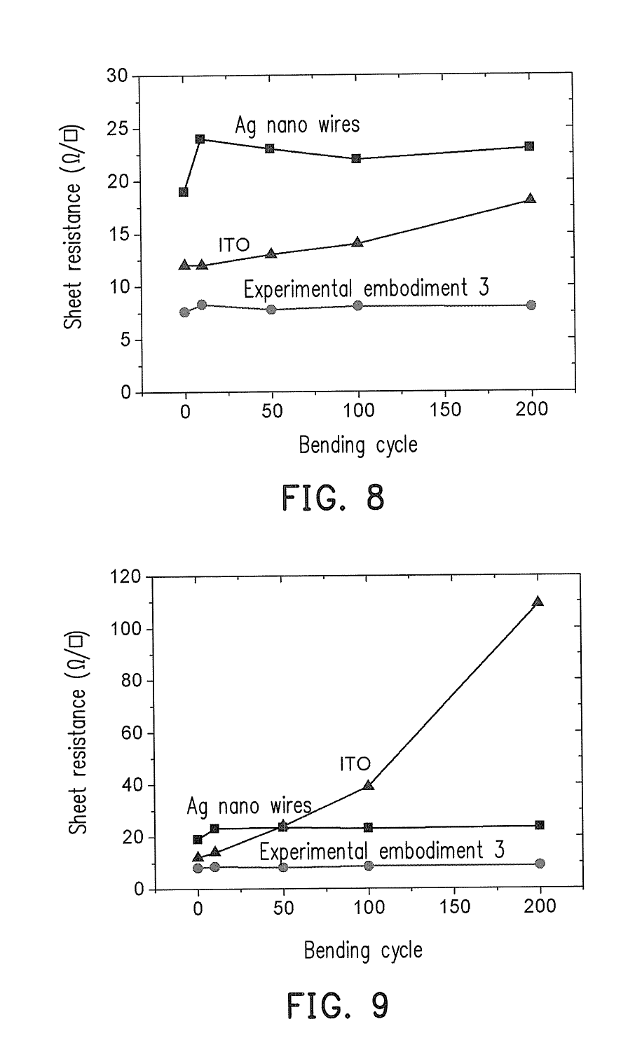

A bending test is performed on the transparent conductive film flexible substrate prepared in experimental embodiment 3 with a radius of curvature of 0.5 cm and compared to a flexible substrate having an ITO (12 Ω/□) coating at the same time. The results are shown in FIG. 8 and FIG. 9.

Referring to FIG. 8, if the conductive layers are bent concave, then it is seen that the sheet resistance of the ITO substrate is increased after bending (maximum increase of 50%). The sheet resistance of the conventional Ag NW is increased at the beginning of the bending and then stays flat (maximum increase of 26%). The continuous phase Ag NW junction in experimental embodiment 3 prepared by a reduced metal maintains good resistance performance (maximum increase of 9%).

Referring to FIG. 9, if the conductive layers are bent convex, then it is seen that the sheet resistance of the ITO substrate is significantly increased after bending (9 times greater after being bent 200 times), indicating the ITO is likely ruptured. The sheet resistance of the conventional Ag NW is similarly increased at the beginning of the bending and then stays flat (maximum increase of 24%). The conductive layer of experimental embodiment 3 still maintains good resistance performance (maximum increase of 10%).

Therefore, it can be known from test 1 that, the variation of sheet resistance of the conductive structure of the disclosure after being bent 200 times with a radius of curvature of 0.5 cm is less than 20%.

Test 2

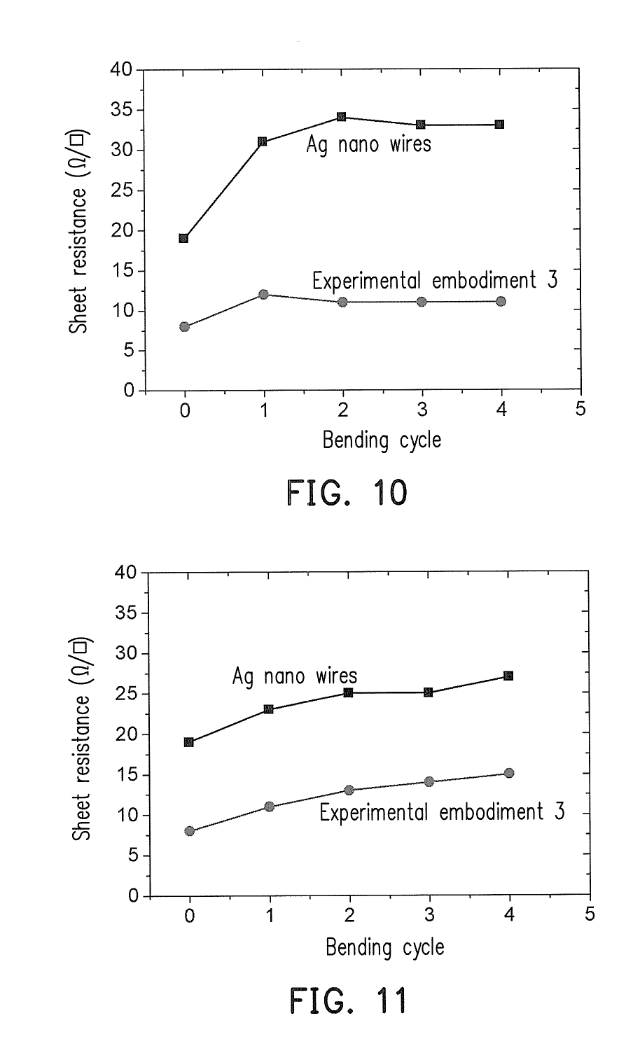

A bending test is performed on the transparent conductive film flexible substrate prepared in experimental embodiment 3 with a radius of curvature of 0.5 mm. The results are shown in FIG. 10 and FIG. 11.

Referring to FIG. 10, if the conductive layers are bent concave, then it is seen that the sheet resistance of the conventional Ag NW is increased after being bent once, and then stays flat (maximum increase of 15 Ω/□). The continuous phase Ag NW junction in experimental embodiment 3 prepared by a reduced metal continues to maintain good resistance performance (maximum increase of 4 Ω/□).

Referring to FIG. 11, if the conductive layers are bent convex, then it can be seen that the variation of sheet resistance of the conventional Ag NW and the continuous phase Ag NW junction of the present application prepared by a reduced metal are still maintained at a certain level (the initial value was increased from 7 Ω/□).

Therefore, it can be known from test 2 that, the variation of sheet resistance of the conductive structure of the disclosure after being bent 4 times with a radius of curvature of 0.5 mm is less than 50%.

Test 3

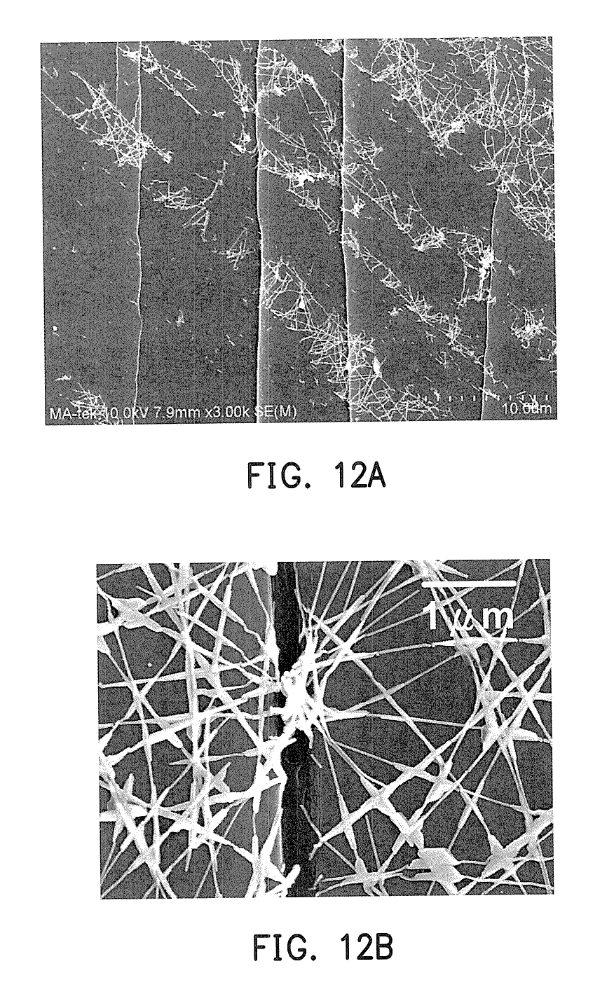

The difference in resistance variation between the conventional NW and the conductive structure of experimental embodiment 3 when the conductive layer of each thereof is bent concave can be described by the SEM micrographs of FIG. 12A and FIG. 12B. Since the bending curvature is small, cracks are generated on the plastic substrate as in, for instance, test 2, and the conventional NW used in test 3 is not covered and protected by an overcoat, the adhesion of the NW is poor and the NW peels off from the substrate (refer to FIG. 12A), thus causing the sheet resistance to increase. The structure of experimental embodiment 3 is exemplified by not being covered by an overcoat, but due to the firm structure of the NW, a peeling effect is not generated (refer to FIG. 12B). At the same time, at the rupture locations of the plastic substrate (PET substrate), the conductive lines are not interrupted due to the continuous phase NW.

The structure of experimental embodiment 3 may maintain good and stable sheet resistance.

### Experimental Embodiment 4

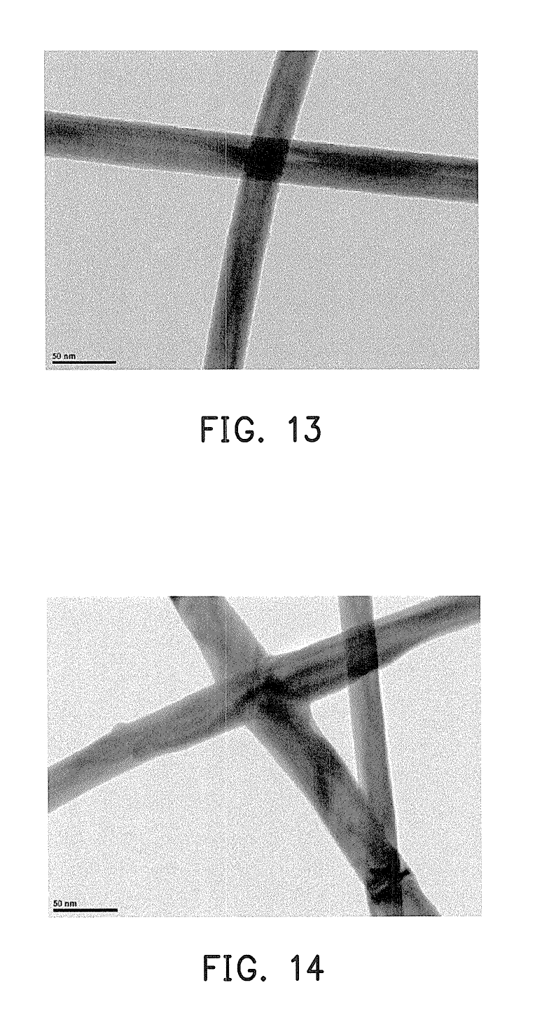

A coating solution of Ag NW is coated on a glass substrate through a slot-die to obtain a transparent conductive film with a sheet resistance of 24 Ω/□. The transparent conductive film is as the overlapping structure shown in the TEM micrograph of FIG. 13. It can be known from FIG. 13 that, the signal of electrons transmitting through the overlapping portions is less, the overlapping portions are darker in comparison. In other words, the Ag NWs are in contact with one another in an overlapping manner before the reaction.

The preparation of the metal reducing solution includes, for instance: adding 3 mL of an aqueous solution of 0.25M NaOH to 5 mL of an aqueous solution of 0.06M AgNO₃ to generate Ag₂O precipitation. After stirring, an aqueous solution of 0.05M NH₃ is added to the Ag₂O mixture via titration until Ag₂O is completely reacted and is no longer visible after stirring. A Ag(NH₃)₂⁺ complex ion compound is thus formed. 0.25 mL of an aqueous solution of glucose with a concentration of 1% is added to the Ag(NH₃)₂⁺ solution to initiate the reduction reaction of Ag. Suspended matter then results in the solution, wherein the suspended matter is Ag metal formed by the reduction.

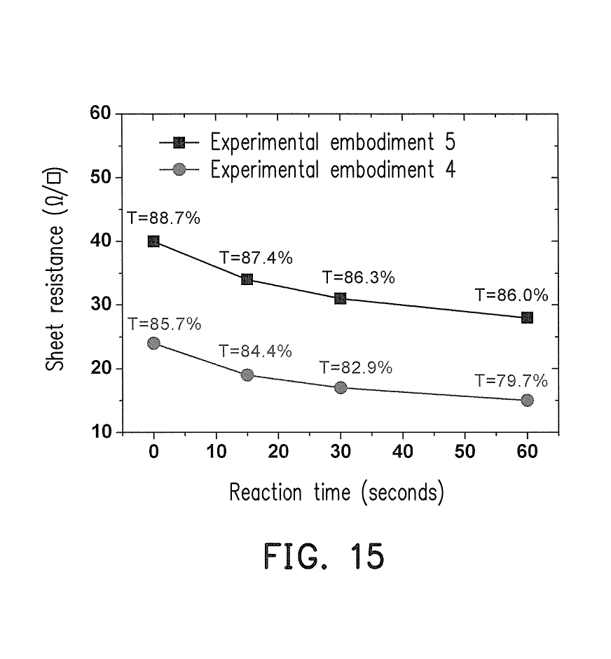

A substrate coated with Ag NW is respectively immersed in the reaction solution for, for instance, 15 seconds, 30 seconds, and 60 seconds so as to grow the Ag formed by the reduction on the Ag NW to form the desired continuous phase structure. The continuous phase structure after the reaction is as shown in the TEM micrograph of FIG. 14. After the Ag NW structure is covered by the reduced silver, the contact portions form a continuous phase structure, and the phenomenon of the wires overlapping on top of one another is absent. The transmittance (T) at the 550 nm wavelength and the sheet resistance of the conductive film after the reaction are measured. The results are as shown in FIG. 15.

### Experimental Embodiment 5

A coating solution of Ag NW is coated on a glass substrate through a slot-die to obtain a transparent conductive film with a sheet resistance of 40 Ω/□.

A metal reducing solution is prepared using the same method as experimental embodiment 4, and then a substrate coated with the Ag NW is respectively immersed in the reaction solution for, for instance, 15 seconds, 30 seconds, and 60 seconds so as to grow the Ag formed by the reduction on the Ag NW to form the desired continuous phase structure. The transmittance at the 550 nm wavelength and the sheet resistance of the conductive film after the reaction are measured. The results are shown in FIG. 15.

It can be known from FIG. 15 that, the sheet resistance of the conductive film of experimental embodiment 4 after the reaction is respectively decreased to 19 Ω/□, 17 Ω/□, and 15Ω/□. The sheet resistance of the conductive film of experimental embodiment 5 after the reaction is also decreased, and the transmittance can be maintained at 86.0% or above.

In an embodiment of the disclosure, a conductive structure of continuous nano metal wires is formed. The conductive structure covers the metal at overlapping connecting portions of network nano metal wires with a metal chemical reduction method. The bending reliability of the conductive film may be increased and the sheet resistance of the overlapping structure formed by the nano metal wires may be decreased. If the conductive structure of an embodiment of the disclosure is applied in a device such as an OLED, an OPV, or a TP, then the conductive structure may replace a conductive layer in the device and be used as an electrode or an auxiliary electrode.

Although the disclosure has been described with reference to the above embodiments, it will be apparent to one of the ordinary skill in the art that modifications and variations to the described embodiments may be made without departing from the spirit and scope of the disclosure. Accordingly, the scope of the disclosure will be defined by the attached claims not by the above detailed descriptions.

What is claimed is:

1. A conductive structure, comprising:
an overlapping structure formed by nano metal wires, wherein the overlapping structure has at least one connecting portion; and
a reduced metal layer covering the nano metal wires at the connecting portions.

2. The conductive structure of claim 1, wherein the reduced metal layer is a metal formed by a reduction reaction.

3. The conductive structure of claim 1, wherein a cross-sectional width of the connecting portions is at least 1.5 times greater than a cross-sectional height thereof.

4. The conductive structure of claim 1, wherein the reduced metal layer further covers the nano metal wires not at the connecting portions.

5. The conductive structure of claim 4, wherein a cross-sectional width of the nano metal wires covered by the reduced metal layer is at least 1.5 times greater than a cross-sectional height thereof.

6. The conductive structure of claim 1, wherein the overlapping structure is a layered or network structure.

7. The conductive structure of claim 1, wherein a material of each of the reduced metal layer and the nano metal wires is the same or different.

8. The conductive structure of claim 1, wherein a material of the nano metal wires comprises silver, copper, nickel, or an alloy thereof.

9. The conductive structure of claim 1, wherein the nano metal wires comprise a covering structure formed by a combination of a plurality of metal layers.

10. The conductive structure of claim 1, wherein a material of the reduced metal layer comprises silver, copper, nickel, titanium, or an alloy thereof

11. The conductive structure of claim 1, wherein a variation of a sheet resistance of the conductive structure after being bent 200 times with a radius of curvature of 0.5 cm is less than 20%.

12. The conductive structure of claim 1, wherein a variation of a sheet resistance of the conductive structure after being bent 4 times with a radius of curvature of 0.5 mm is less than 50%.

13. A device, comprising a plurality of electrode structures, wherein at least one of the electrode structures is the conductive structure of claim 1.

14. The device of claim 13, wherein the device comprises an organic light-emitting diode (OLED), an organic solar cell (OPV), or a touch panel (TP).
